(19) United States
(12) Patent Application Publication
(10) Pub. No.: US 2007/0236138 A1
(43) Pub. Date: Oct. 11, 2007

(54) Organic light-emitting diodes with nanostructure film electrode(s)

(76) Inventors: Liangbing Hu, Los Angeles, CA (US); George Grunner, Los Angeles, CA (US); Jianfeng Li, Chicago, IL (US); Tobin Marks, Evanston, IL (US)

Correspondence Address: VENABLE LLP, P.O. BOX 34385, WASHINGTON, DC, 20043-9998, US

(21) Appl. No.: 11/698,994

(22) Filed: Jan. 29, 2007

Related U.S. Application Data
(63) Continuation-in-part of application No. PCT/US05/47315, filed on Dec. 27, 2005.
(60) Provisional application No. 60/833,789, filed on Jul. 28, 2006.

(51) Int. Cl. H01J 1/62; H01J 9/00

(52) U.S. Cl. 313/504; 445/24; 977/724; 977/788

(57) ABSTRACT

Organic light-emitting diodes (OLEDs) comprising at least one nanostructure-film electrode, and fabrication methods thereof are discussed. The nanostructure-film is preferably transparent, and may be deposited on a preferably-transparent substrate using a variety of techniques. A different material may be used to planarize the nanostructure-film and/or otherwise improve OLED performance.

This application claims priority to U.S. Provisional Patent Application No. 60/833,789, filed Jul. 28, 2006, and entitled “ORGANIC LIGHT-EMITTING DIODES WITH SINGLE-WALLED CARBON NANOTUBE FILM ANODES,” and PCT Application No. US/2005/047315, filed Dec. 27, 2005, and entitled “COMPONENTS AND DEVICES FORMED USING NANOSCALE MATERIALS AND METHODS OF PRODUCTION,” which are hereby incorporated herein by reference.

### FIELD OF THE INVENTION

The present invention relates in general to light emitting diodes, and more particularly to an organic light emitting diode comprising a nanostructure-film.

### BACKGROUND

Polymer-based and small molecule-based organic light-emitting diodes (OLEDs) are rapidly approaching large-scale commercialization, driven by such attractions as low cost, fast response, and applications in large-area flexible displays, as well by recent advances in efficiencies and operational lifetimes.

OLEDs are dual injection devices in which holes and electrons are injected from an anode and cathode, respectively, into the active layer to produce light emission via exciton decay. At least one of the cathode and anode must be at least semi-transparent, so as to allow light emitted from the active layer to pass through.

As used herein, a layer of material or a sequence of several layers of different materials is said to be “transparent” when the layer or layers permit at least 50% of the ambient electromagnetic radiation in relevant wavelengths to be transmitted through the layer or layers. Similarly, layers which permit some but less than 50% transmission of ambient electromagnetic radiation in relevant wavelengths are said to be “semi-transparent.”

Currently, the most commonly used transparent electrodes are transparent conducting oxides (TCOs), specifically indium-tin-oxide (ITO) on glass. However, ITO, with its relatively brittle structure, can be an inadequate solution for many emerging applications (e.g., flexible optoelectronic devices such as many OLEDs), and the indium component of ITO is rapidly becoming a scarce commodity. Moreover, ITO has significant limitations for current and future generations of OLEDs, including diffusion of oxygen into proximate organic charge transporting/emissive layers, significant absorption in the blue region, a relatively low work function and corrosion susceptibility. Hence, a more robust, abundant and compatible transparent conductor material is required.

### SUMMARY OF INVENTION

The present invention provides a nanostructure-film for use as a transparent conductive material. Specifically, an OLED device with at least one nanostructure-film electrode is provided. Nanostructure-films include, but are not limited to, those comprising network(s) of nanotubes, nanowires, nanoparticles and/or graphene flakes.

In an OLED according to a preferred embodiment of the present invention, the nanostructure-film comprises at least one transparent network of single-walled carbon nanotubes (SWNTs). Theoretical and experimental studies have established the work function of transparent conducting films composed of randomly distributed SWNTs to be in the range of 4.7-5.2 eV (more than satisfying OLED electrode requirements), and such SWNT networks have been demonstrated as substantially more mechanically robust than ITO films (making them ideal for OLEDs and other flexible displays). Furthermore, carbon is one of the most abundant elements on Earth, and does not share many of ITO's aforementioned limitations with respect to OLED applications.

Regardless of the type of nanostructure used, the nanostructure-film is preferably transparent and deposited on an at least semi-transparent substrate. This substrate may additionally be flexible, comprising, for example, polyethylene terephthalate (PET), polyethylene naphthalate (PEN) and/or similar plastics.

An OLED according to a further embodiment of the present invention comprises at least one active layer adjacent to the nanostructure-film electrode(s). This active layer is preferably polymer-based and/or small molecule-based.

A different material (e.g., a conducting polymer) may be deposited between the nanostructure-film electrode and the active layer. This material may serve to fill porosity in the nanostructure-film, and/or as part of a hole transporting layer. Additionally or alternatively, this material may comprise a passivation layer (e.g., a fluoropolymer).

OLEDs according to embodiments of the present invention can display emission intensities exceeding, for example, 400 cd/m². Additionally, such OLEDs may have turn-on voltages of as little as, for example, 4.5V.

A method of fabricating an OLED according to the present invention may comprise depositing a transparent nanostructure-film electrode onto a substrate, depositing at least one active layer over the nanostructure-film electrode, and depositing a cathode over the active layer. This method may further comprise depositing a hole transporting layer between the nanostructure-film and the active layer.

A portion of the hole transporting layer may comprise a different material deposited on the transparent nanostructure-film, wherein the different material fills porosity in the transparent nanostructure-film and/or planarizes the nanostructure-film. Additionally or alternatively, this different conductive material may be mixed with nanostructures as part of the process of forming the nanostructure-film. Note, electrode layers may be deposited directly onto an active, buffer and/or polymer layer (e.g., without use of a substrate).

Other features and advantages of the invention will be apparent from the accompanying drawings and from the detailed description. One or more of the above-disclosed embodiments, in addition to certain alternatives, are provided in further detail below with reference to the attached figures. The invention is not limited to any particular embodiment disclosed.

### BRIEF DESCRIPTION OF THE DRAWINGS

The invention is better understood from reading the following detailed description of the preferred embodiments, with reference to the accompanying figures in which:

FIG. 1A is an atomic force microscope (AFM) image of a nanostructure film according to an embodiment of the present invention, specifically one comprising a stamp-transferred SWNT network on a PET substrate.

FIG. 1B shows the transmittance versus wavelength in the visible and near-infrared range for nanostructure-films according to embodiments of the present invention.

FIG. 1C shows the DC resistance versus transmittance of nanostructure-films according to embodiments of the present invention at 550 nm for various nanostructure densities.

FIG. 2A outlines the chemical structures of poly(9,9-dioctylfluorene-co-benzothiadiazole) (BT), poly(3,4-ethylenedioxythiophene) (PEDOT) and 4,4′-bis[(p-trichlorosilylpropylphenyl) phenylamino]biphenyl (TPD-Si2).

FIG. 2B is a schematic representation of an OLED architecture according to an embodiment of the present invention.

FIG. 3A is an AFM image of a nanostructure-film according to another embodiment of the present invention, specifically one comprising a SWNT network spin-coated with PEDOT:PSS.

FIG. 4A shows current versus voltage responses for devices according to embodiments of the present invention.

FIG. 4B shows luminance versus voltage responses for devices according to embodiments of the present invention.

FIG. 4C shows current efficiency versus voltage responses for devices according to embodiments of the present invention.

FIG. 5 outlines a method of fabricating OLEDs according to an embodiment of the present invention.

Features, elements, and aspects of the invention that are referenced by the same numerals in different figures represent the same, equivalent, or similar features, elements, or aspects in accordance with one or more embodiments of the system.

### DETAILED DESCRIPTION OF THE PREFERRED EMBODIMENTS

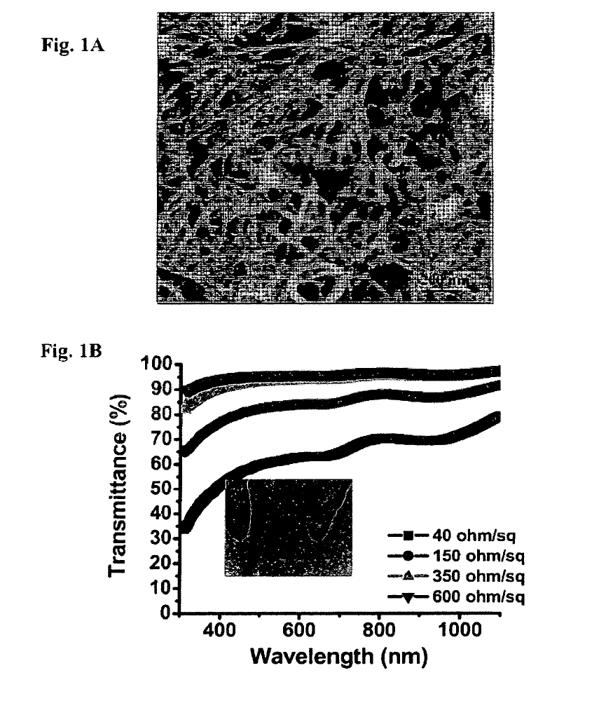

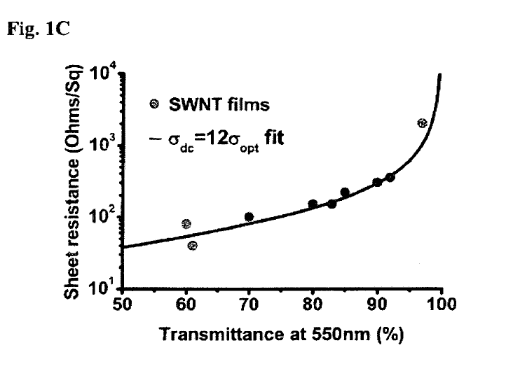

Referring to FIG. 1A, a nanostructure-film according an embodiment of the present invention comprises a two-dimensional random network of nanostructures. This film is preferably at least semi-transparent and electrically conductive, and preferably comprises at least one network of single-walled carbon nanotubes (SWNTs).

Transparent conducting nanostructure-films composed of randomly distributed SWNTs (i.e., networks) have been demonstrated as substantially more mechanically robust than ITO. Additionally, theoretical and experimental studies have established that the work function of SWNT networks can be in the range of 4.7-5.2 eV—sufficiently high to meet at least the anode requirements for such optoelectronic devices as OLEDs. Moreover, SWNTs can be deposited using a variety of low-impact methods (e.g., it can be solution processed), and comprise carbon, which is one of the most abundant elements on Earth.

SWNT networks may be fabricated by, for example, suspending SWNT powders in water with a surfactant, followed by sonication, filtering and washing. Exemplary methods of making nanostructure networks are described in PCT application US/2005/047315 “Components and Devices Formed Using Nanoscale Materials and Methods of Production,” which is hereby incorporated by reference herein in its entirety. Specifically, SWNTs (e.g., ˜2-10 microns long) may be solubilized in a solvent to form a solution or suspension. Thereby, the solvent may comprise a dilute solution of well-dispersed SWNTs in water and surfactant (e.g., sodium dodecyl sulfate (SDS)). This solution may be subsequently sonicated to form a surfactant-stabilized suspension.

This suspension may be deposited on a substrate through a variety of techniques including, but not limited to, spraying, drop casting, inkjet printing, dip coating and transfer printing. The substrate (e.g., glass and/or polyethylene terephthalate (PET), polyethylene naphthalate (PEN) and similar plastics) may be heated (e.g., to about 100° C. or higher) during deposition to avoid forming liquid pools. Similarly, the substrate may be further heated after deposition of the nanostructure-film to evaporate the surfactant.

Referring to FIG. 1(B), transmittance of the above-fabricated nanostructure-film may be only weakly dependent on wavelength, in accord with the neutral color of the film. For nanostructure sheets having different thicknesses, the sheet resistance and transmittance may be related by the equation:

$$T = {( 1 + \frac{1}{2 {R}_{s}} \sqrt{\frac{{μ}_{0}}{{ɛ}_{0}}} \frac{{σ}_{op}}{{σ}_{dc}} )}^{2} = {( 1 + \frac{188 ( Ω )}{{R}_{s}} \frac{{σ}_{op}}{{σ}_{dc}} )}^{- 2}$$

where the sheet resistance (Rₛ) is inversely proportional to the film thickness (t), e.g., Rₛ=1/σ_{dc}t. Optical conductivity (σₒₚ) in a sample film according to an embodiment of the present invention was about σₒₚ=200 S/cm.

Referring to FIG. 1(C), the sheet resistance and transmittance of a film of a certain thickness according to an embodiment of the present invention may also be described by the above equation.

The atomic force microscope (AFM) image of FIG. 1(A) evidences the successful deposition of a relatively uniform nanostructure-film on a substrate.

In an exemplary experiment, SWNT powders were suspended in water with the surfactant sodium dodecyl sulfate (SDS), and then sonicated and filtered. Subsequent washing with DI water was used to remove the SDS (note: other suitable surfactants may be used). In exemplary embodiments, the solution was filtered through an alumina filter.

Once the above film was formed on the filter, it was deposited onto a substrate (e.g., PET) using a PDMS stamping method (note: other methods including, but not limited to, spraying, drop casting, inkjet printing, and dip coating may be used to deposit nanostructure-film(s) according to embodiments of the present invention).

The PDMS stamp of the exemplary method was fabricated from a silicon master made by a photolithography process, wherein a silicon wafer was dehydration baked (e.g., for 15 minutes at 150° C.), with photoresist (e.g., SU-8) subsequently spun on the wafer (e.g., for 30 minutes at 4000 rpm, to produce a 20 micron thick SU-8 layer). After a brief soft bake (e.g., at 65° C. for 3 minutes and 90° C. for 4 minutes), the photoresist layer was patterned by photo-exposure (e.g., using 405 nm light for 75 seconds at a power of 8 mW/cm² in hard contact mode). After a brief post-exposure bake (e.g., identical to the soft bake), the SU-8 was developed (e.g., using SU-8 developer for 5 minutes). Finally, the developed SU-8 was rinsed (e.g., using IPA) and blown dry. Note: this silicon master may be prepared using a variety of photoresists with varying thicknesses.

A silicone elastomer base and a curing agent was then mixed in a ratio of 1:10, cured for two hours in vacuum to remove bubbles, and poured onto the silicon master, which may first be pretreated (e.g., with 2 hours of vacuum silanization in a vapor of (Tridecafluoro-1,1,2,2-trichlorosilane). After, for example, one hour of vacuum curing and two hours of oven baking at 80° C., a PDMS stamp was peeled away from the silicon master.

This PDMS stamp was then contacted with the SWNT film on the alumina filter, and transferred to a substrate. Conformal contact between the stamp and the films on the filters induces wetting, which may in turn transfer the film from the filter to the stamp. The alumina filter may then be reused for additional filtration and transfer printing cycles.

The SWNT film was transferred from the PDMS stamp to the substrate by contacting the substrate and heating it. As with the alumina filter, the stamp may then be reused for additional transfer printing cycles.

An OLED according to a further embodiment of the present invention may additionally incorporate a different material (e.g., a conducting and/or passivation polymer) that serves to fill porosity in the nanostructure (e.g., SWNT) film. The different material may be mixed with nanostructures prior to deposition (e.g., to form a composite), and/or may be deposited separately (e.g., and allowed to diffuse into the nanostructure network).

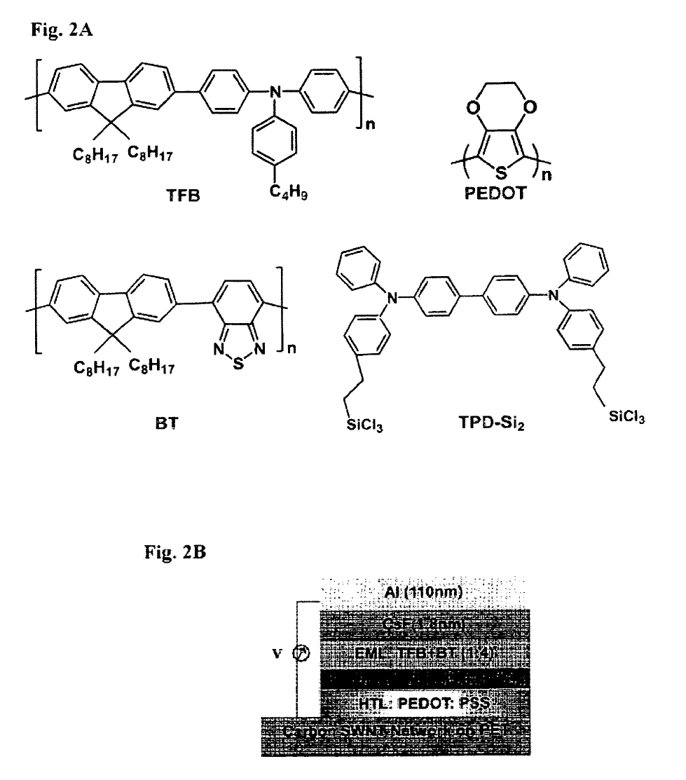

Referring to FIG. 2A, a nanostructure-film as fabricated and deposited in the exemplary embodiment above may be used to form an OLED device comprising such materials as poly(9,9-dioctylfluorene-co-benzothiadiazole) (BT), poly(3,4-ethylenedioxythiophene) (PEDOT) and/or 4,4′-bis[(p-trichlorosilylpropylphenyl) phenylamino]biphenyl (TPD-Si2).

For example, a polymer blend hole-transporting layer (HTL) comprising a cross-linkable hole-transporting organosiloxane material (e.g., TPD-Si2) and a hole-transporting polymer (e.g., TFB), which may also serve as an effective PLED electron-blocking layer (EBL), may be spin-coated onto a clean SWNT film or PEDOT:PSS-coated SWNT film to form a double-layer HTL.

After baking these HTL films in a vacuum oven (e.g., at 90° C. for 1-2 hours), the PEDOT:PSS may then be spin-coated onto the SWNT sheet (e.g., at 2500 rpm for 1 minute) and subsequently dried (e.g., at 120° C. for 8 minutes). Additionally or alternatively, a mixture of PEDOT:PSS and methanol (Baytron P: MeOH=1:2) may be spin-coated onto the SWNT sheet (e.g., at 600 rpm for 1 minute, then at 2500 rpm for 1 min) and subsequently dried (e.g., at 120° C. for 2 hours in a vacuum oven).

Next, a charge transport/emissive layer (EML) (e.g., a TFB+BT blend (TFB:BT=1:4)) may be spin-coated onto the HTL-coated substrates (e.g., from xylene solution) and subsequently dried (e.g., in a vacuum oven at ˜90° C. overnight).

Finally, another electrode layer may be deposited onto the EML (e.g., CsF and Al thermally evaporated in an inert-atmosphere glove box with a vacuum of <10ˆ-6 Torr using a shadow mask to define the electrode areas.

Referring to FIG. 2B, a first embodiment of the present invention comprises a nanostructure-film (e.g., comprising a SWNT network) deposited on PET. This film acts as, for example, and anode, and may be coated or mixed with a different conductive material (e.g., a conducting polymer such as PEDOT:PSS) that, to some extent, fills porosity in the film. Next, an HTL (e.g., TPD-Si2 and/or TFB) may be deposited on the anode and may comprise, for example, a single or double layer (e.g., with PEDOT-PSS: MeOH). An organic EML may then be deposited between the HTL and a subsequently-deposited cathode (e.g., comprising CsF and Al).

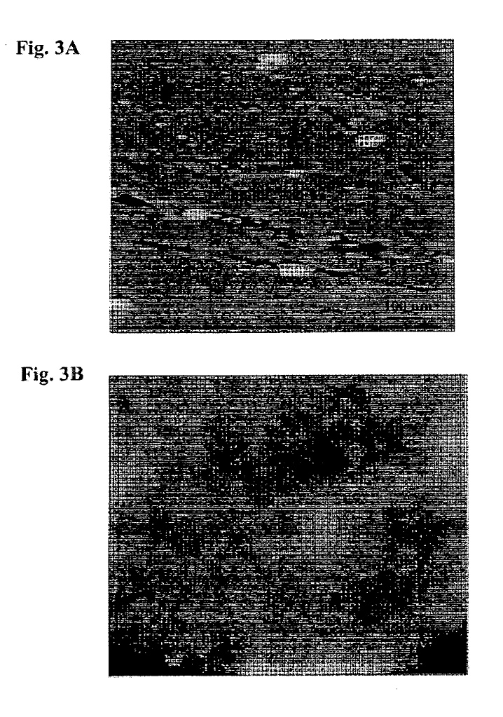

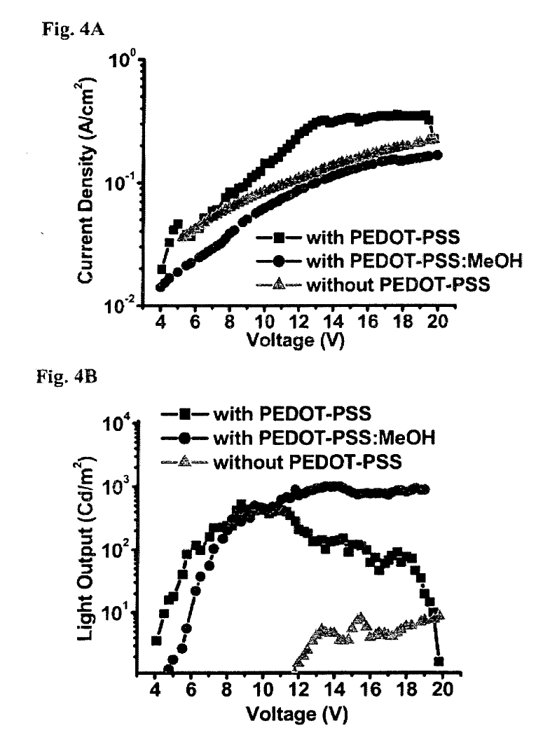

Referring to FIGS. 3A and 3B, the RMS roughness of a nanostructure-film coated with the aforementioned different conductive material can be very low (e.g., 0.96 nm for a SWNT film spin-coated with PEDOT-PSS: MeOH in FIG. 3A, and 4 nm for a SWNT film spin-coated with only PEDOT-PSS in FIG. 3B). The planarization of nanostructure-films by such different conductive materials, which may also act as a hole transporting and/or buffer layer(s), may decrease the hole-injection barrier from the nanostructure-film, thereby decreasing device leakage currents and turn-on voltage.

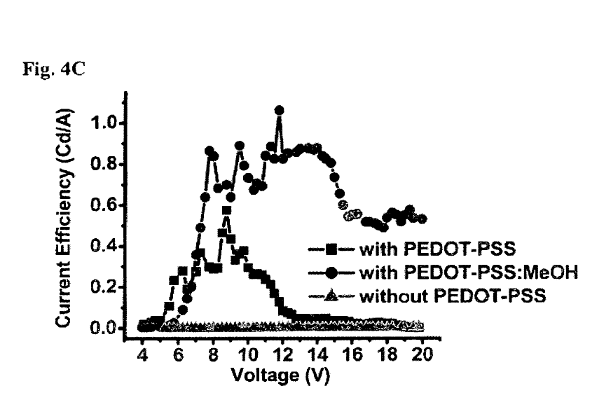

Referring to FIG. 4, Polymer-based OLEDs according to embodiments of the present invention include, for example:

i) SWNT/TFB+TPD-Si2/TFB+BT/CsF/Al,

ii) SWNT/PEDOT-PSS/TFB+TPD-Si2/TFB+BT/CsF/Al, and

iii) SWNT/PEDOT-PSS: MeOH/TFB+TPD-Si2/TFB+BT/CsF/Al.

The current density, luminance and current efficiency versus bias responses for these three embodiments are compared in FIGS. 4A, 4B and 4C respectively. As is apparent from this data, dramatic enhancement in device metrics occurred in a preferred embodiment that incorporates PEDOT-PSS.

Organic layers other than those described above may be used, e.g., alternate HTLs and EMLs. Such layers include, but are not limited to: F8BT, PVK, PBD, NPB, Alq2, etc. Likewise, buffer layers other than CsF may be used, e.g., alumina, LiF, LiF/Mg:Ag, etc; and metal cathodes other than aluminum may be used, e.g., silver.

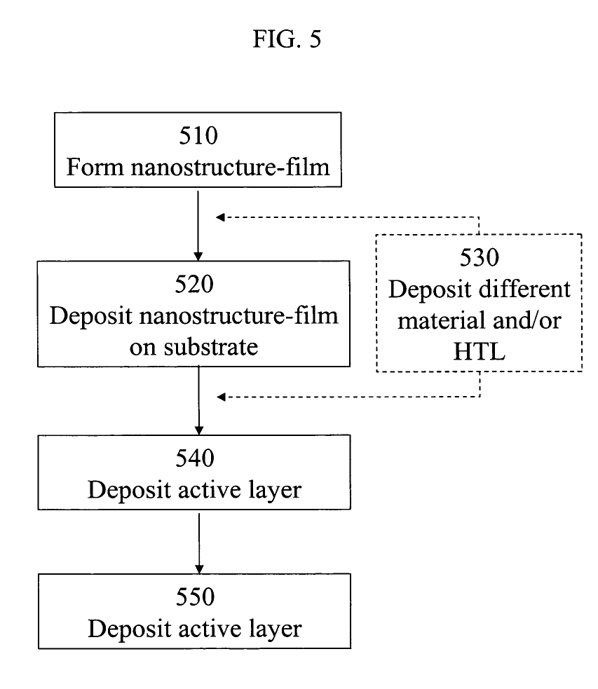

Referring to FIG. 5, a method of fabricating an OLED according to the present invention comprises first forming a nanostructure-film 510. This nanostructure-film may comprise not only a network of nanostructures, but also a different material used to fill porosity in said network. Regardless of its composition, this nanostructure-film is preferably transparent.

Once formed, the nanostructure-film may be deposited onto a, preferably at least semi-transparent, substrate 520. This substrate is preferably flexible and transparent, and may comprise, for example, polyethylene terephthalate (PET), polyethylene naphthalate (PEN) and/or similar plastics. Deposition may be performed through a variety of techniques including, but not limited to, spraying, drop casting, inkjet printing, dip coating and transfer printing.

A different material and/or hole transporting layer (HTL) may be deposited on the nanostructure-film 530. This layer may serve to fill porosity in the underlying nanostructure film, and/or otherwise improve device performance (e.g., by increasing charge transport between the active layer and the nanostructure-film electrode). Additionally or alternatively, this different material may serve as an encapsulation and/or passivation layer.

At least one active layer may then be deposited 540 over the nanostructure-film and/or different material and/or HTL. This active layer is preferably organic, and may be polymer and/or small molecule-based.

Finally, a second electrode may be deposited over the active layer 550. This second electrode is preferably a cathode, and may comprise, for example, a conventional metal and/or another nanostructure-film.

The present invention has been described above with reference to preferred features and embodiments. Those skilled in the art will recognize, however, that changes and modifications may be made in these preferred embodiments without departing from the scope of the present invention. These and various other adaptations and combinations of the embodiments disclosed are within the scope of the invention.

What is claimed is:

1. An organic light emitting diode (OLED), comprising at least one nanostructure-film electrode.

2. The OLED of claim 1, further comprising at least one active layer adjacent to the nanostructure-film electrode.

3. The OLED of claim 2, further comprising a transparent substrate, wherein the nanostructure-film electrode is deposited on the substrate.

4. The OLED of claim 3, wherein the substrate is flexible.

5. The OLED of claim 4, wherein the nanostructure-film electrode comprises at least one network of single-walled carbon nanotubes.

6. The OLED of claim 5, further comprising a hole transporting layer between the active layer and the nanostructure-film electrode.

7. The OLED of claim 1, further comprising a passivation polymer, wherein the passivation polymer fills porosity in the nanostructure film.

8. The OLED of claim 1, further comprising a conducting polymer, wherein the conducting polymer fills porosity in the nanostructure film.

9. The OLED of claim 1, wherein a maximum emission intensity of the OLED is greater than 400 cd/m².

10. The OLED of claim 9, having a turn on voltage of less than 12V.

11. The OLED of claim 1, wherein a maximum emission intensity of the OLED is between 450 cd/m² and 1000 cd/m².

12. The OLED of claim 1, wherein the maximum emission intensity of the OLED is between 500 cd/m² and 800 cd/m².

13. The OLED of claim 1, having a turn on voltage of less than 12V.

14. The OLED of claim 1, having a turn on voltage between 4.5V and 11V.

15. The OLED of claim 1, wherein the nanostructure-film electrode comprises at least one network of single-walled carbon nanotubes.

16. A method of fabricating an organic light emitting diode (OLED), comprising:
depositing a transparent nanostructure-film;
depositing at least one active layer; and
depositing a cathode, wherein the active layer is sandwiched between the transparent nanostructure-film and the cathode.

17. The method of claim 16, further comprising depositing a hole transporting layer between the nanostructure-film and the active layer.

18. The method of claim 16, further comprising depositing a different material on the transparent nanostructure-film, wherein the different material fills porosity in the transparent nanostructure-film.

19. The method of claim 16, wherein the different material is at least one of a conducting polymer and a passivation polymer.

20. The method of claim 16, wherein the transparent nanostructure-film comprises at least one network of single-walled carbon nanotubes.
